(19) United States
(12) Patent Application Publication
(10) Pub. No.: US 2026/0317949 A1
(43) Pub. Date: Oct. 15, 2026

(54) poly-Si thin films preparation method based on thermal field design of vertical double-layer hot-wire array

(71) Applicant: Nanchang Hangkong University, Nanchang City (CN)

(72) Inventors: Yingmin Wang, Nanchang City (CN); Li Cai, Nanchang City (CN); Pengliang Liu, Nanchang City (CN)

(73) Assignee: Nanchang Hangkong University, Nanchang City (CN)

(21) Appl. No.: 19/323,133

(22) Filed: Sep. 9, 2025

(30) Foreign Application Priority Data
Apr. 11, 2025 (CN) 202510455470.5

(51) Int. Cl. C30B 28/12; C30B 29/06; C30B 33/02

(52) U.S. Cl. CPC C30B 28/12; C30B 29/06; C30B 33/02

(57) ABSTRACT

A poly-Si thin films preparation method based on thermal field design of a vertical double-layer hot-wire array is provided. An interlayer spacing of a double-layer hot-wire array, and current of double-layer hot wires are adjusted to change a surface temperature of hot wires and a range of a high-temperature thermal decomposition zone, which enlarges a silane pyrolysis duration and pyrolysis space, promotes secondary silane pyrolysis, effectively controls the composition and concentration distribution of silane pyrolysis intermediates reaching a substrate surface, and increases ratio of SiH/SiH2 active radicals. The poly-Si thin films is deposited at a vacuum degree of 0.5 Pa-5.0 Pa, a substrate temperature of 200-560° C., and a deposition duration of 10-60 min, the substrate temperature is raised to 200-650° C. after the deposition, and the grown poly-Si thin films is subjected to vacuum annealing to obtain a poly-Si thin films with high crystallinity.

### REFERENCE TO PRIOR APPLICATION

This application claims priority to Chinese Patent Application 202510455470.5, filed on Apr. 11, 2025, which is incorporated herein by reference.

### TECHNICAL FIELD

The present disclosure relates to the technical field of thin films preparation, and in particular to a poly-Si thin films preparation method based on a thermal field design of a vertical double-layer hot-wire array.

### BACKGROUND

With the mass production of tunnel oxide passivated contact (TOPCon) solar cells, the cell recombination loss has become a current research hotspot. To ensure the efficient selective transmission of photogenerated carriers, it is necessary to enhance the passivation performance of back surfaces of solar cells and simultaneously increase the crystallization rate of poly-Si thin films so as to improve the carrier concentration and mobility.

Poly-Si thin films for TOPCon solar cells in the prior art are prepared mainly through the following two methods, but the methods have the following drawbacks:
1. Plasma enhanced chemical vapor deposition (PECVD): Due to the presence of a large number of free radicals, cations, and anions in silane under the condition of plasma, as well as a relatively high operating reaction pressure, active radicals with different charges are prone to generate large particle agglomerates.
2. Low-pressure chemical vapor deposition (LPCVD): The thermal field distribution of LPCVD is relatively difficult to design, and non-uniform pyrolysis across partial regions and significant fluctuations in intermediate concentrations result in an increase in the defect concentration of the poly-Si thin films. Additionally, a pyrolysis source is far away from a center position of a quartz tube (a silicon wafer at the center position), active radicals are prone to agglomeration during transmission, and there exists silicon microparticle agglomerates in a reaction chamber, which directly affects the uniformity and stability of the poly-Si thin films.

### SUMMARY

An objective of the present disclosure is to provide a poly-Si thin films preparation method based on a thermal field design of a vertical double-layer hot-wire array, so as to solve the above technical problems.

In order to achieve the above objective, the present disclosure provides a technical solution as follows:

The poly-Si thin films preparation method based on a thermal field design of a vertical double-layer hot-wire array includes the following steps:
(1) Substrate pretreatment: performing pretreatment on a monocrystalline silicon substrate;
(2) thin films deposition: using the thermal field design of a vertical double-layer hot-wire array and high-temperature hot-wire silane thermal decomposition technology to deposit and grow poly-Si thin films on the monocrystalline silicon substrate; and
(3) annealing: using vacuum annealing technology to anneal the grown poly-Si thin films.

In some embodiments, a first-layer hot wire and a second-layer hot wire are arranged in three array configurations, i.e., a vertically aligned double-layer hot-wire array with a head-to-head parallel configuration, a vertically aligned double-layer hot-wire array with a head-to-foot parallel configuration, and a vertically staggered double-layer hot-wire array, to achieve the silane pyrolysis by using a thermal field of the vertical double-layer hot-wire array.

In some embodiments, either layer of hot wire is powered by an independent power supply, hot-wire current of either layer is independently controlled to adjust a surface temperature of hot wire and a range of high-temperature thermal decomposition zone, adjust a composition ratio and concentration distribution of silane pyrolysis intermediates, and increase a ratio of SiH/SiH2 active radicals.

In some embodiments, the using the thermal field design of a vertical double-layer hot-wire array and high-temperature hot-wire silane thermal decomposition technology to deposit and grow poly-Si thin films on the monocrystalline silicon substrate includes: heating the monocrystalline silicon substrate to 200-560° C., introducing a mixed gas of SiH4 and H2, controlling a flow ratio of the mixed gas of SiH4 and H2 to be 1:3-1:9, adjusting a gate valve to maintain a vacuum degree of a growth chamber at 0.5 Pa-5.0 Pa, turning on hot-wire power supplies respectively, adjusting the current of a first-layer hot wire until the first-layer hot wire has a surface temperature of 1700-1950° C., and then adjusting the current of a second-layer hot wire until the second-layer hot wire has a surface temperature of 1750-2250° C., where the surface temperature of the second-layer hot wire is always higher than the surface temperature of the first-layer hot wire, active radicals from silane pyrolysis are deposited on a surface of the monocrystalline silicon substrate, and a poly-Si thin films with a thickness of 20-100 nm is grown under the conditions that a temperature of the monocrystalline silicon substrate is 200-560° C. and a deposition duration is 10-60 min.

In some embodiments, the using vacuum annealing technology to anneal the grown poly-Si thin films includes:
stopping the introduction of SiH4 and H2 gases, turning off the hot-wire power supplies, raising the temperature of the monocrystalline silicon substrate with the formed poly-Si thin films to 200-650° C., and performing vacuum annealing on the grown poly-Si thin films for 10-60 min.

In some embodiments, the performing pretreatment on a monocrystalline silicon substrate includes:
placing the cleaned and dried monocrystalline silicon substrate on a sample holder of a hot-wire chemical vapor deposition growth chamber, successively turning on a dry vacuum pump and a molecular pump to make a vacuum degree of the growth chamber reach below 1.0×10−3 Pa, heating the monocrystalline silicon substrate to 150° C., and degassing the monocrystalline silicon substrate for half an hour.

In some embodiments, a flow rate and ratio of SiH4 and H2 are controlled to adjust a vacuum pressure of the growth chamber, and temperatures and spacings of the first-layer hot wire and the second-layer hot wire are adjusted to control the pyrolysis duration and pyrolysis space of silane, which achieves control over the composition and concentration of active radicals reaching the substrate, depositing of the thin films under a reasonable temperature system, and vacuum annealing of the deposited thin films, thereby improving the crystallization rate of the poly-Si thin films.

Compared with the prior art, the present disclosure has the beneficial effects as follows:

According to the poly-Si thin films preparation method based on a thermal field design of a vertical double-layer hot-wire array provided in the embodiments of the present disclosure, the vertical double-layer hot-wire array is used for silane pyrolysis to prepare the poly-Si thin films with high crystallinity. After multiple pyrolysis of silane, the composition ratio and energy of active radicals reaching the substrate surface are well controlled, and after the vacuum annealing treatment of the grown thin films, the crystallization rate of the poly-Si thin films is significantly improved, thereby having good application prospects for the development of photovoltaic cells and optoelectronic devices.

### BRIEF DESCRIPTION OF DRAWINGS

The accompanying drawings described herein are used for achieving further understanding of the present disclosure, and constitute a part of The present disclosure. The illustrative embodiments of the present disclosure and the description of the illustrative embodiments serve to explain the present disclosure and are not to be construed as unduly limiting the present disclosure.

FIG. 1 is a schematic diagram of a layout of a vertical double-layer hot-wire array and silane pyrolysis in a growth chamber in the present disclosure.

FIG. 2 is a schematic structural diagram of a first-layer hot wire.

FIG. 3 is a schematic structural diagram of a second-layer hot wire.

FIG. 4 is a three-dimensional schematic diagram of a first distribution (head-to-head parallel alignment) of a first-layer hot wire and a second-layer hot wire.

FIG. 5 is a left view of a first distribution (head-to-head parallel alignment) of a first-layer hot wire and a second-layer hot wire.

FIG. 6 is a three-dimensional schematic diagram of a second distribution (head-to-foot parallel alignment) of a first-layer hot wire and a second-layer hot wire.

FIG. 7 is a left view of a second distribution (head-to-foot parallel alignment) of a first-layer hot wire and a second-layer hot wire.

FIG. 8 is a three-dimensional schematic diagram of a third distribution (double-layer staggered) of a first-layer hot wire and a second-layer hot wire.

FIG. 9 is a left view of a third distribution (double-layer staggered) of a first-layer hot wire and a second-layer hot wire.

### DETAILED DESCRIPTION OF EMBODIMENTS

Specific embodiments of the present disclosure will be described in detail herein. Preferred embodiments of the present disclosure are illustrated in the accompanying drawings, and the accompanying drawings are intended to graphically supplement the written description in the specification and enable the visual and intuitive understanding of each technical feature and the overall technical solution of the present disclosure. However, the accompanying drawings shall not be construed as limiting the protection scope of the present disclosure.

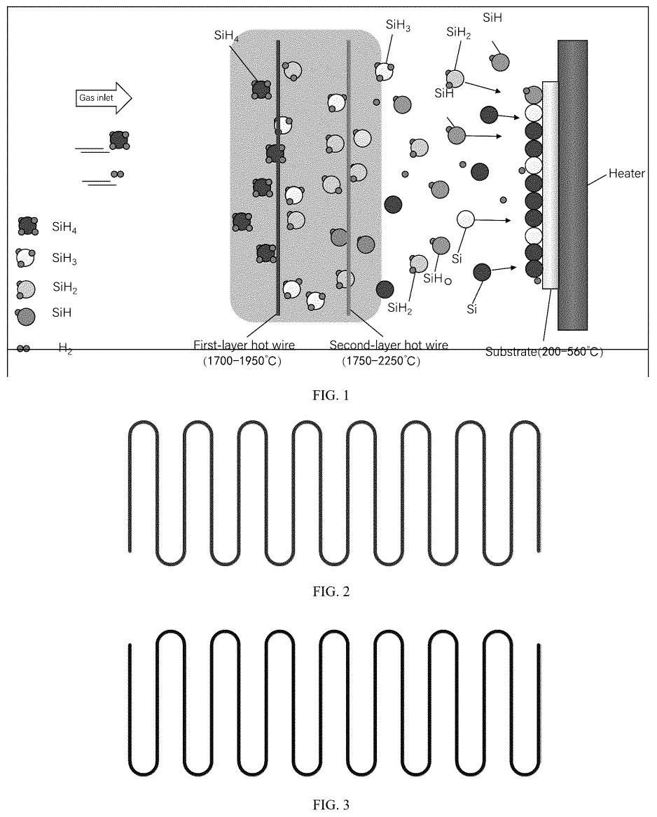

With reference to FIGS. 1 to 9, in an embodiment of the present disclosure, there is provided a poly-Si thin films preparation method based on a thermal field design of a vertical double-layer hot-wire array, and the method includes the following steps:
(1) Substrate pretreatment: perform pretreatment on a monocrystalline silicon substrate.

For example, the pretreatment includes: place the cleaned and dried monocrystalline silicon substrate on a sample holder of a hot-wire chemical vapor deposition growth chamber, successively turn on a dry vacuum pump and a molecular pump to make a vacuum degree of the growth chamber reach below 1.0×10−3Pa, heat the monocrystalline silicon substrate to 150° C., and degas the monocrystalline silicon substrate for half an hour.

(2) Thin films deposition: use the thermal field design of a vertical double-layer hot-wire array and high-temperature hot-wire silane thermal decomposition technology to deposit and grow poly-Si thin films on the monocrystalline silicon substrate.

As an example, the vertical double-layer hot-wire array is composed of a first-layer hot wire and a second-layer hot wire, and specifically has the following three distribution configurations.

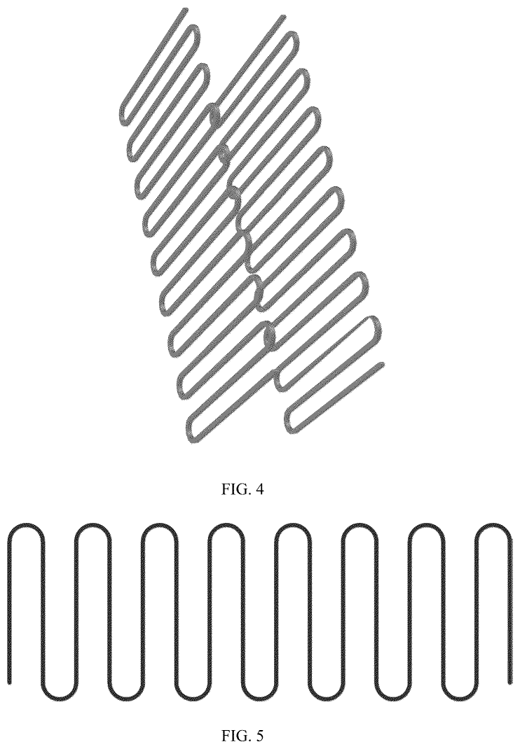

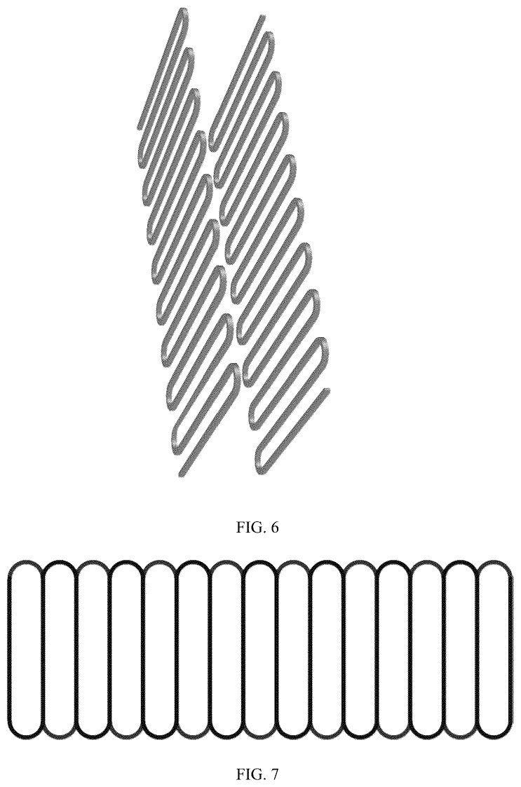

For example, FIGS. 4 and 5 illustrate a first distribution (head-to-head parallel alignment) of the first-layer hot wire and the second-layer hot wire, where the first-layer hot wire and the second-layer hot wire constitute a first vertical double-layer hot-wire array (i.e., a vertically aligned double-layer hot-wire array with a head-to-head parallel configuration). The hot wire on the left in FIG. 4 represent the first-layer hot wire.

For example, FIGS. 6 and 7 illustrate a second distribution (head-to-foot parallel alignment) of the first-layer hot wire and the second-layer hot wire, where the first-layer hot wire and the second-layer hot wire constitute a second vertical double-layer hot-wire array (i.e., a vertically aligned double-layer hot-wire array with a head-to-foot parallel configuration). The hot wire on the left in FIG. 6 represent the first-layer hot wire.

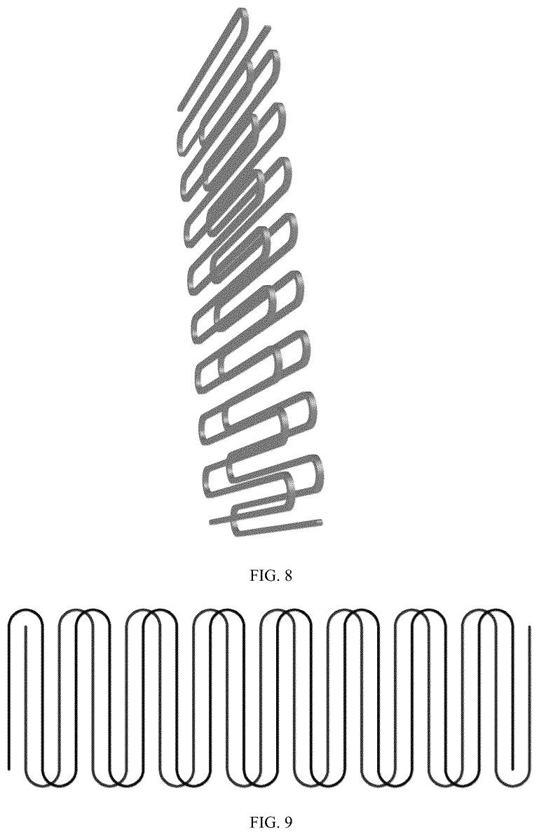

For example, FIGS. 8 and 9 illustrate a third distribution (double-layer staggered) of the first-layer hot wire and the second-layer hot wire, where the first-layer hot wire and the second-layer hot wire constitute a third vertical double-layer hot-wire array (i.e., a vertically staggered double-layer hot-wire array). The hot wire on the left in FIG. 8 represent the first-layer hot wire.

Therefore, the first-layer hot wire and the second-layer hot wire are arranged in three array configurations, i.e., a vertically aligned double-layer hot-wire array with a head-to-head parallel configuration, a vertically aligned double-layer hot-wire array with a head-to-foot parallel configuration, and a vertically staggered double-layer hot-wire array.

It should be understood that the above three vertical double-layer hot-wire arrays with different distribution configurations all achieve the silane pyrolysis by using the thermal field of vertical double-layer hot-wire array. Compared with the hot-wire chemical vapor deposition (CVD) with only a single-layer wire array, the present disclosure has the following advantages: 1. The temperature uniformity of the double-layer hot wires mapped to the substrate surface is enhanced; 2. the probability of collision between silane and hot wires is increased, and the efficiency of silane pyrolysis is improved; 3. by adjusting a spacing of the hot-wire array, the present disclosure adjusts a range of the high-temperature zone, reduces the polymerization of active radicals after pyrolysis, and increases energy of active radicals reaching the substrate surface; 4. the surface temperature of hot wire (hot-wire current) is adjusted to control the composition of active radicals after silane pyrolysis.

In some embodiments, either layer of hot wire is powered by an independent power supply, hot-wire current of either layer is independently controlled to adjust a surface temperature of hot wire and a range of high-temperature thermal decomposition zone, adjust a composition ratio and concentration distribution of silane pyrolysis intermediates, and increase a ratio of SiH/SiH2 active radicals.

Preferably, the vertically staggered double-layer hot-wire array as shown in FIGS. 8 and 9 is adopted to achieve the silane pyrolysis by using the thermal field of the vertically staggered double-layer hot-wire array.

Specifically, the step (2) includes:

heat the monocrystalline silicon substrate to 200-560° C., introduce a mixed gas of SiH4 and H2, control a flow ratio of the mixed gas of SiH4 and H2 to be 1:3-1:9, adjust a gate valve to maintain a vacuum degree of a growth chamber at 0.5 Pa-5.0 Pa, turn on hot-wire power supplies respectively, adjust the current of a first-layer hot wire until the first-layer hot wire has a surface temperature of 1700-1950° C., and then adjust the current of a second-layer hot wire until the second-layer hot wire has a surface temperature of 1750-2250° C., where the surface temperature of the second-layer hot wire is always higher than the surface temperature of the first-layer hot wire, active radicals from silane pyrolysis are deposited on a surface of the monocrystalline silicon substrate, and a poly-Si thin films with a thickness of 20-100 nm is grown under the conditions that a temperature of the monocrystalline silicon substrate is 200-560° C. and a deposition duration is 10-60 min.

Therefore, by controlling the current of the first-layer hot wire and the current of the second-layer hot wire, the surface temperature of the first-layer hot wire reaches 1700-1950° C., and the surface temperature of the second-layer hot wire reaches 1750-2250° C. After silane enters a reaction chamber, silane pyrolysis starts upon exposure to high-temperature hot wires. By adjusting the current of the first-layer hot wire, the current of the second-layer hot wire, and the spacing between the first-layer hot wire and the second-layer hot wire, the present disclosure effectively controls the composition ratio and concentration distribution of silane pyrolysis intermediates (such as SiH3, SiH2, SiH, and other free radicals) reaching the substrate surface. A poly-Si thin films with a thickness of 20-100 nm is obtained under the conditions that the substrate temperature is 200-560° C. and the deposition duration is 10-60 min. The method of the present disclosure improves the silane pyrolysis efficiency through the vertical double-layer hot-wire array, and controls the composition ratio and concentration distribution of active radicals reaching the substrate surface. The poly-Si thin films with the thickness of 20-100 nm is prepared under a reasonable temperature system, and the crystallization quality of the thin films is improved through vacuum annealing treatment.

As an example, in this step, a flow rate and ratio of SiH4 and H2 are controlled to adjust a vacuum pressure of the growth chamber, and temperatures and spacings of the first-layer hot wire and the second-layer hot wire are adjusted to control the pyrolysis duration and pyrolysis space of silane, which achieves control over the composition and concentration of active radicals reaching the substrate, depositing of the thin films under a reasonable temperature system, and vacuum annealing of the deposited thin films, thereby improving the crystallization rate of the poly-Si thin films.

(3) Annealing: use vacuum annealing technology to anneal the grown poly-Si thin films. Specifically, the step (3) includes:
stop the introduction of SiH4 and H2 gases, turn off the hot-wire power supplies, raise the temperature of the monocrystalline silicon substrate with the formed poly-Si thin films to 200-650° C., and perform vacuum annealing on the grown poly-Si thin films for 10-60 min.

To sum up, in the embodiments, the present disclosure prepares the poly-Si thin films with high crystallinity by adopting the thermal field design of a vertical double-layer hot-wire array, high-temperature hot-wire silane thermal decomposition technology, and vacuum annealing technology, and has good application prospects for the development of photovoltaic cells and optoelectronic devices. Specifically, an interlayer spacing of the double-layer hot-wire array, and the current of the double-layer hot wires are adjusted to change the surface temperature of the hot wires and the range of the high-temperature thermal decomposition zone, which enlarges the silane pyrolysis duration and pyrolysis space, promotes the secondary pyrolysis of silane, effectively controls the composition and concentration distribution of silane pyrolysis intermediates (such as SiH3, SiH2, SiH, and other free radicals) reaching the substrate surface, and increases the ratio of SiH/SiH2 active radicals; and the poly-Si thin films is deposited under the conditions that the substrate temperature is 200-560° C. and the deposition duration is 10-60 min, the substrate temperature is raised to 200-650° C. after the deposition, and the grown poly-Si thin films is subjected to vacuum annealing for 10-60 min, to obtain a poly-Si thin films with high crystallinity.

Without conflicting with the above, those skilled in the art may freely combine and superimpose the above additional technical features.

The above are merely preferred embodiments of the present disclosure, and all technical solutions that achieve the objectives of the present disclosure through substantially the same means fall within the protection scope of the present disclosure.

What is claimed is:

1. A poly-Si thin films preparation method based on a thermal field design of a vertical double-layer hot-wire array, comprising the following steps:
(1) Substrate pretreatment: performing pretreatment on a monocrystalline silicon substrate;
(2) thin films deposition: using the thermal field design of a vertical double-layer hot-wire array and high-temperature hot-wire silane thermal decomposition technology to deposit and grow poly-Si thin films on the monocrystalline silicon substrate;
(3) annealing: using vacuum annealing technology to anneal the grown poly-Si thin films;
the using the thermal field design of a vertical double-layer hot-wire array and high-temperature hot-wire silane thermal decomposition technology to deposit and grow poly-Si thin films on the monocrystalline silicon substrate comprises:
heating the monocrystalline silicon substrate to 200-560° C., introducing a mixed gas of SiH4 and H2, controlling a flow ratio of the mixed gas of SiH4 and H2 to be 1:3-1:9, adjusting a gate valve to maintain a vacuum degree of a growth chamber at 0.5 Pa-5.0 Pa, turning on hot-wire power supplies respectively, adjusting current of a first-layer hot wire until the first-layer hot wire has a surface temperature of 1700-1950° C., and then adjusting current of a second-layer hot wire until the second-layer hot wire has a surface temperature of 1750-2250° C., wherein the surface temperature of the second-layer hot wire is always higher than the surface temperature of the first-layer hot wire, active radicals from silane pyrolysis are deposited on a surface of the monocrystalline silicon substrate, and a poly-Si thin films with a thickness of 20-100 nm is grown under the conditions that a temperature of the monocrystalline silicon substrate is 200-560° C. and a deposition duration is 10-60 min;
the first-layer hot wire and the second-layer hot wire are arranged in three array configurations, i.e., a vertically aligned double-layer hot-wire array with a head-to-head parallel configuration, a vertically aligned double-layer hot-wire array with a head-to-foot parallel configuration, and a vertically staggered double-layer hot-wire array, to achieve silane pyrolysis by using a thermal field of the vertical double-layer hot-wire array; and
either layer of hot wire is powered by an independent power supply, hot-wire current of either layer is independently controlled to adjust a surface temperature of hot wire and a range of a high-temperature thermal decomposition zone, adjust a composition ratio and concentration distribution of silane pyrolysis intermediates, and increase a ratio of SiH/SiH2 active radicals.

2. The poly-Si thin films preparation method based on a thermal field design of a vertical double-layer hot-wire array according to claim 1, wherein the using vacuum annealing technology to anneal the grown poly-Si thin films comprises:
stopping introduction of SiH4 and H2 gases, turning off the hot-wire power supplies, raising the temperature of the monocrystalline silicon substrate with the formed poly-Si thin films to 200-650° C., and performing vacuum annealing on the grown poly-Si thin films for 10-60 min.

3. The poly-Si thin films preparation method based on a thermal field design of a vertical double-layer hot-wire array according to claim 2, wherein the performing pretreatment on a monocrystalline silicon substrate comprises:
placing the cleaned and dried monocrystalline silicon substrate on a sample holder of a hot-wire chemical vapor deposition growth chamber, successively turning on a dry vacuum pump and a molecular pump to make a vacuum degree of the growth chamber reach below 1.0×10−3 Pa, heating the monocrystalline silicon substrate to 150° C., and degassing the monocrystalline silicon substrate for half an hour.

4. The poly-Si thin films preparation method based on a thermal field design of a vertical double-layer hot-wire array according to claim 1, wherein a flow rate and ratio of SiH4 and H2 are controlled to adjust a vacuum pressure of the growth chamber, and temperatures and spacings of the first-layer hot wire and the second-layer hot wire are adjusted to control a pyrolysis duration and a pyrolysis space of silane, which achieves control over a composition and concentration of active radicals reaching the substrate, depositing of the thin films under a reasonable temperature system, and vacuum annealing of the deposited thin films, thereby improving a crystallization rate of the poly-Si thin films.
